(19) United States
(12) Patent Application Publication
(10) Pub. No.: US 2014/0085779 A1
(43) Pub. Date: Mar. 27, 2014

(54) DISPLAY PANEL DEVICE AND A DISPLAY APPARATUS COMPRISING THE DISPLAY PANEL DEVICE

(71) Applicants: KONINKLIJKE PHILIPS ELECTRONICS N.V., BA EINDHOVEN (NL); TP VISION HOLDING B.V., AE EINDHOVEN (NL)

(72) Inventor: Pieter Jan Delva, Kortrijk (BE)

(73) Assignee: TP VISION HOLDING B.V., AE EINDHOVEN (NL)

(21) Appl. No.: 13/643,976

(22) PCT Filed: Apr. 14, 2011
(86) PCT No.: PCT/IB2011/051619

§ 371 Date: Sep. 6, 2013

(30) Foreign Application Priority Data
Apr. 26, 2010 (EP) EP 10161036.8

(51) Int. Cl. H05K 7/14

(52) U.S. Cl. CPC H05K 7/1417
USPC 361/679.01

(57) ABSTRACT

A display panel device (1) comprises a front frame (3), a rear frame (5) and a display panel assembly (7) substantially positioned between the front frame and the rear frame. The front frame is provided with a front frame face (3a) directed to the display panel assembly and the rear frame is provided with a rear frame face (5a) directed to the display panel assembly. The display panel device further comprises a securing arrangement for mutually securing the front frame, the display panel assembly and the rear frame. The securing arrangement includes a front sub-frame (13), a rear sub-frame (15) and an adhering provision (9a) for adhering the front sub-frame to the front frame face and for adhering the rear sub-frame to the rear frame face. The securing arrangement further includes an attaching device (9b) for detachably attaching the front sub-frame and the rear sub-frame to each other. Due to the applied features the display panel device can be assembled and, if wished, disassembled in an easy way.

### FIELD OF THE INVENTION

The invention relates to a display panel device comprising a front frame, a rear frame and a display panel assembly substantially positioned between the front frame and the rear frame.

### BACKGROUND OF THE INVENTION

The European Patent Application EP 1 586 935 A2 discloses a liquid crystal display television receiver provided with a cabinet divided into a front cabinet, having a display window, and a back cabinet. A liquid crystal display panel is incorporated in the cabinet by means of a mounting cover. Such a mounting cover is created from a thin plate of a metal material, wherein by bending the edges the thin plate at right angles a perimeter wall is formed. The perimeter wall is provided with mounting lugs for making contact with folded lugs of the liquid crystal display panel to be mounted. In the mounted position the mounting lugs and folded lugs face each other in the longitudinal direction of the perimeter wall. The mounting lugs are provided with insertion holes corresponding to screw holes of the folded lugs. When the liquid crystal display panel is attached to a mounting cover, fixing screws are passed through the insertion holes and screwed into the screw holes. After mounting the liquid crystal display panel to the mounting cover, the mounting cover is disposed inside the front cabinet in a way that its display surface faces the display window. Then, the liquid crystal display panel is fixed to the front cabinet by aligning holes formed in the mounting cover with screw holes formed in the front cabinet, passing screws through the aligning holes and screwing the screws into the screw holes. A drawback of the liquid crystal display panel disclosed in the above-mentioned patent application is that its building-in into a display apparatus is laborious because of the many necessary components, such as a specific mounting cover and various lugs and screws, and the many necessary steps to realize building-in. Another drawback is the time-consuming labor, at the end of the lifetime of the display apparatus to disassemble the built-in liquid crystal display panel into its basic components because of the applied specific mounting with a plurality of screw fixations.

The Japanese Patent Application JP 2004 258291 A discloses a flat panel display device having a housing formed by a bottom and side walls, and further having a panel display module comprising a bezel, a liquid crystal panel and a plastic frame accommodated into the housing. A screw clamp hole is arranged on a fitting piece part of the plastic frame. A screw inserting hole is arranged on an outer peripheral piece part of the bezel. The fitting piece part and the outer peripheral piece part are fixed to each other via the screw clamp hole and the screw inserting hole.

### OBJECT AND SUMMARY OF THE INVENTION

It is an object of the invention to provide a display panel device which can be assembled and, if wished, disassembled in an easy way.

This object is achieved by the display panel device as described in claim 1. More particularly, the display panel device according to the invention comprises a front frame, a rear frame and a display panel assembly substantially positioned between the front frame and the rear frame, the front frame being provided with a front frame face directed to the display panel assembly and the rear frame being provided with a rear frame face directed to the display panel assembly, and further comprises a securing arrangement for mutually securing the front frame, the display panel assembly and the rear frame, wherein the securing arrangement includes a front sub-frame, a rear sub-frame and an adhering provision for adhering the front sub-frame to the front frame face and for adhering the rear sub-frame to the rear frame face, and wherein the securing arrangement includes an attaching device for detachably attaching the front sub-frame and the rear sub-frame to each other. The front frame and the rear frame constitute a housing in which the securing arrangement is accommodated, wherein the housing is provided with an entrance substantially opposite to the attaching device.

The display panel device according to the invention offers the possibility for a design wherein the securing arrangement is not visible from the outside. In view of the wish to design display panel devices more and more as an integral module of the cabinet of a display apparatus, such a design is very attractive and aesthetically justified. The securing arrangement, which is preferably entirely accommodated in the housing, is covered by the front frame and rear frame and in principle not visible from the outside. The attaching device may include a number of screws, locking pins, plugs and the like, inserted into corresponding holes provided into the sub-frames. The entrance, which can be one or more entrances, serves to make the attaching device approachable from the outside in order to operate the attaching device.

To make the display assembly of the display panel device according to the invention accessible for service purposes it is favorable to use the attaching device for disassembling the front sub-frame and the rear sub-frame from each other. The connection between the front frame and the front sub-frame, as well as the connection between the rear frame and the rear sub-frame, lasts. Contrary thereto, it is favorable to use the adhering provision for disassembling the display panel device according to the invention at the end-of-life. For instance, by heating the display panel device, for example to put the display panel device into an oven, the adhesion function of the adhering provision disappears above a certain, dependent from the applied adhesion material, temperature. In this way the display panel device falls apart into its specific basic components without a lot of effort.

It is noted that an adhesive, also called glue, is a mixture in a liquid or semi-liquid state for adhering or bonding items together. Adhesives may come from natural or synthetic sources. Some modern adhesives are extremely strong, and are becoming increasingly important in modern construction and industry. Adhesives usually require a controlled temperature to cure or set. Some adhesives disintegrate or lose their strengths at a temperature higher than the temperature during normal use.

It is further noted that the front frame, also called a bezel, and the rear frame, also called a back cover, can be made of any suitable material, such as glass, plastics and metal, materials which are already commonly used. The front sub-frame and the rear sub-frame can be made of a plastics or a metal.

The display assembly may be of any available type of flat panel display, such as liquid crystal displays (LCDs), plasma displays, organic light-emitting diode displays (OLEDs), light-emitting diode displays (LED), electroluminescent displays (ELDs), surface-conduction electron-emitter displays (SEDs) and field emission displays (FEDs), also called nano-emissive displays (NEDs).

It is to be noted that the United States Patent Application Publication US 2006/0164567 A1 discloses a liquid crystal display module which includes a liquid crystal display element, a frame member having a frame-shaped part which is arranged at a displaying surface side of the liquid crystal display element and having a display window exposing a displaying surface of the liquid crystal display element. The frame member is provided with side walls which are extended from the frame-shaped part along a thickness direction of the liquid crystal display element and are provided with holes. The liquid crystal display module includes a mould having sides provided with inserts having internal threads formed therein at locations corresponding to the holes in the side walls of the frame member. By screwing up fitting screws having external threads formed thereon to the respective inserts through holes formed in an exterior case of a display portion of a notebook-size personal computer and formed in a metal side beam provided between the liquid crystal display module and the exterior case, and through the holes in frame member, the liquid crystal display module is fitted to the personal computer. The screws are visible at the outside of the exterior case.

It is further to be noted that the United States Patent Application Publication US 2007/0290617 A1 discloses a plasma display panel module which includes a plasma display panel having a rear plate and a front plate installed in parallel with the rear plate. The module further includes an aluminum plate in parallel with the rear plate, an adhesive provided between the aluminum plate and the rear plate, and four fixing devices. The fixing devices serve for fixing the plasma display panel to the aluminum plate, so that when the adhesive becomes less effective due to the heat generated by the plasma display panel and the environment humidity, the plasma display panel is still fixed to the aluminum plate.

Furthermore, it is to be noted that the U.S. Pat. No. 7,245,076 B2 discloses an assembly structure of a plasma display apparatus and a plasma display panel. The plasma display apparatus comprises a main frame, wherein the plasma display panel is fixed to the main frame by means of strips of adhesive tape. The adhesive tape is made of materials of high heat conductivity and serves to transfer the heat generated in the plasma display panel to the main frame of the plasma display apparatus.

Furthermore, it is to be noted that the Japanese Patent Application JP 2007 310258 A discloses a flat panel display, provided with a liquid crystal display panel and a front cabinet covering the front face of the display panel. A buffer member is arranged between the display panel or a front bezel being a structure to hold the display panel and the back face of the front cabinet. The buffer member is inserted in between two or more ribs erected so as to face each other and to be perpendicular to the back face of the front cabinet. The buffer member surrounds the display screen of the display panel.

Furthermore, it is to be noted that the United States Patent US 2010/073595 A1 discloses a liquid crystal display assembly which includes an enclosure, a lens received in an opening of the enclosure and a shielding frame. The shielding frame is mounted on a printed circuit board. A double-sided tape attaches the shielding frame, the enclosure and the lens.

Furthermore, it is to be noted that the United States Patent US 2009/147171 A1 discloses a display device which is held together by an upper container section and a lower container section jointed together. The upper and lower container sections interlock with one another by virtue of each having a shape corresponding to that of a frusto rectangular pyramid shell. The upper container section wraps over and about the lower container section.

A practical embodiment of the display panel device according to the invention is characterized in that the display panel assembly is sandwiched between the front sub-frame and the rear sub-frame. Because of the applied feature a compact and reliable construction is obtained.

A preferred embodiment of the display panel device according to the invention is characterized in that the front sub-frame and the rear sub-frame create an overlapping area, in which area the front sub-frame and the rear sub-frame are detachably attached to each other.

A preferred embodiment of the display panel device according to the invention is characterized in that the overlapping area is formed by a front sub-frame part of the front sub-frame and a rear sub-frame part of the rear sub-frame, wherein both sub-frame parts are substantially oriented perpendicularly to at least one of the front frame face and the rear front face. In this embodiment the front sub-frame and the rear sub-frame are each hook-shaped in cross-section, wherein the front sub-frame part and the rear sub-frame part face each other. In this way the front sub-frame and the rear sub-frame are easily detachably attachable to each other from outside the display panel device.

A practical embodiment of the display panel device according to the invention is characterized in that the attaching device includes a number of fixing elements, preferably screws or alternatively locking pins, plugs and the like, inserted into corresponding holes provided into the sub-frames. In case screws are applied at least the holes in the sub-frame situated farther within are preferably screw-holes. The exact number of fixing elements depends on among others the dimensions of the display panel device. In a practical embodiment having a screen size, i.e. a window size, of about 40″ to 42″ about three or four screws are applied on each side of the display panel device.

A practical embodiment of the display panel device according to the invention is characterized in that the adhering provision includes an adhesive tape, preferably double-sided adhesive tape. In this embodiment the adhesive tape is in-between the sub-frames, on the one hand, and the frames, on the other hand. Assembling is very easy. Adhesive tapes are commercially available in a variety of types, as the adhesives are as above mentioned.

A preferred embodiment of the display panel device according to the invention is characterized in that the adhesive has such a characteristic that the adhesive, and thus the adhesive tape, loses its adhesive function above a predetermined temperature. This feature provides the possibility to easily disassemble the display panel device, by simply heating the device, for instance in a oven. The tape loses automatically its adhesive strength at a certain temperature, whereby the device disintegrates in its basic components. Applying the right adhesive tape is a matter of selecting the tape having the right characteristics.

A preferred embodiment of the display panel device according to the invention is characterized in that the entrance is closable by a removable cover. In this embodiment the display panel device is entirely closed during normal use. This prevents unwanted entry into the device and improves the appearance of the device.

A practical embodiment of the display panel device according to the invention is characterized in that the entrance is formed by a circumferential gap extending between a side front wall of the front frame and a side rear wall of the rear frame. Preferably, this gap is closed by an appropriate cover, preferably in the form of an insert band, such as a decoration strip. Alternatively, the entrance is formed by a plurality of openings opposite to the attaching device, particularly the screws and the like.

A practical embodiment of the display panel device according to the invention is characterized in that the front frame has the shape of a window frame and is provided with a display window. Preferably, the rear frame is plate-shaped, wherein the rear frame may be substantially uninterrupted or provided with openings.

The display panel device according to the invention can be applied as part of a forward integration concept, as well as for standard display applications. Particularly in the mentioned concept application the front frame and/or the rear frame should have aesthetic looks.

The invention also relates to a display apparatus comprising the display panel device according to the invention. The display apparatus can be any kind of apparatus having a flat panel display. Examples are television apparatus, monitors, laptops, notebooks and ebooks. The display apparatus according to the invention has benefits similar to the above elucidated benefits of the display panel device according to the invention.

With reference to the claims it is noted that the invention relates to all possible combinations of features stated in the independent and dependent claims.

These and other aspects of the invention are apparent from and will be elucidated with reference to the examples described hereinafter.

### BRIEF DESCRIPTION OF THE DRAWINGS

FIG. 1 partly shows a schematic cross-section of an embodiment of the display panel device according to the invention;

FIG. 2 is a front view in perspective of the embodiment partly shown in FIG. 1;

FIG. 3 is a rear view in perspective of the embodiment partly shown in FIG. 1; and

FIG. 4 is a rear view of an embodiment of the display apparatus according to the invention.

### DETAILED DESCRIPTION OF THE EMBODIMENTS

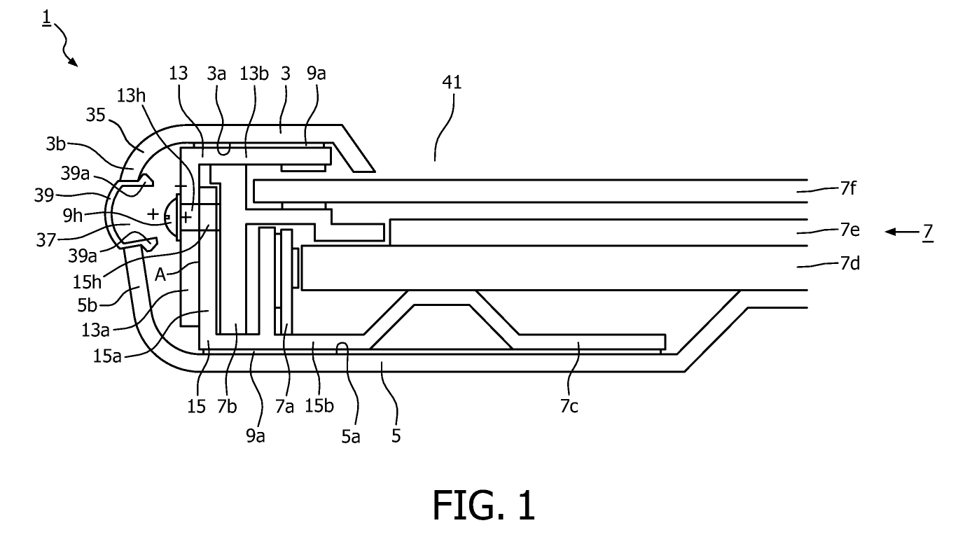

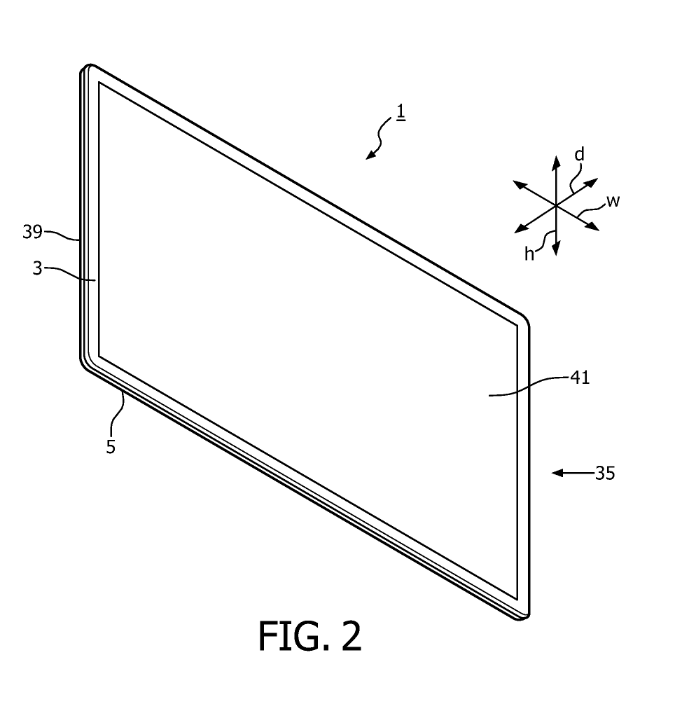

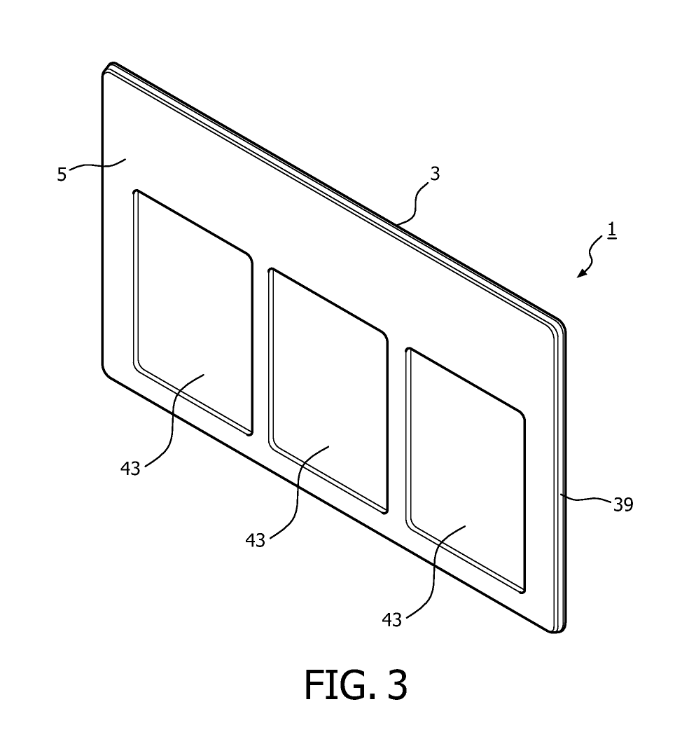

The display panel device 1 depicted in FIGS. 1 to 3 comprises a front frame 3, a rear frame 5 and a display panel assembly 7 positioned between the front frame 3 and the rear frame 5. The display panel assembly may be a known panel assembly. In this embodiment a LED display panel assembly 7 is applied. The applied LED display panel assembly 7 comprises as main parts among others a LED printed circuit board 7a, a guide panel 7b, a heat sink 7c of aluminum, a light guide panel (LGP) 7d, an optical stack 7e and a thin-film transistor (TFT) screen 7f. The front frame 3 is provided with a front frame face 3a directed to the display panel assembly 7. The rear frame 5 is provided with a rear frame face 5a directed to the display panel assembly 7. Both frames 3 and 5 are made in this example of a usual plastic.

The display panel device 1 further comprises a securing arrangement for securing the front frame 3, the display panel assembly 7 and the rear frame 5 to each other. The securing arrangement includes a front sub-frame 13, a rear sub-frame 15 and an adhering provision 9a for adhering the front sub-frame 13 to the front frame face 3 and for adhering the rear sub-frame 15 to the rear frame face 5. The front frame 3 and the rear frame 5 form a housing 35 having a width direction w, a height direction h and a depth direction d. The front frame 3, also called a bezel, is window-frame-shaped, is provided with a window 41, being an opening in the front frame, and comprises a front side wall 3b. In this example the window 41 has a diagonal dimension of 40″. The rear frame 5 is plate-shaped, comprises a rear side wall 5b and, in this example, is provided with three functional areas 43, such as openings or recesses for accommodating and fixing several components. The front side wall 3b and the rear side wall 5b are opposite and define an entrance 37, which is in this example slot-shaped.

The front sub-frame 13 has a front sub-frame part 13a and a further front sub-frame part 13b, which parts make in this example an angle of 90 degrees or about 90 degrees with each other. The rear sub-frame 15 has a front sub-frame part 15a and a further front sub-frame part 15b, which parts make in this example an angle of 90 degrees or about 90 degrees with each other. In this example both sub-frames are aluminum window-shaped bodies being in cross section corner-profile shaped. The rear sub-frame 15 and the heat sink 7c may be one component. The sub-frame parts 13a and 15a are oriented perpendicularly to the frame faces 3a and 5a.

The adhering provision is formed in this example by a double-sided adhesion tape 9a, i.e. a tape having two adhesive surfaces, one at each of its sides. A part of the adhesion tape 9a is provided on the front frame face 3a for adhering the further front sub-frame part 13b to the front frame 3. Another part of the adhesion tape 9a is provided on the rear frame face 5a for adhering the further rear sub-frame part 15b to the rear frame 5. One essential characteristic of the adhesion tape 9 is its adhesive strength to maintain the connection between the front frame 3 and the front sub-frame 13, and the rear frame 5 and the sub-rear frame 15 under all circumstances during normal use of the display panel device. Another essential characteristic of the adhesion tape 9a is its property to lose its adhesive strength when heated above a certain temperature, for instance 100 or about 100 Celsius degrees. The weakening temperature of many plastics is about 90° C.

The securing arrangement further includes an attaching device for detachably attaching the front sub-frame 13 and the rear sub-frame 15 to each other. In this example the attaching device comprises a plurality of screws 9h, of which only one is depicted in the drawings. In the present example 14 screws are applied, distributed among the width direction w and the height direction h. The front sub-frame part 13a of the front sub-frame 13 is provided with holes 13h, while the rear sub-frame part 15a of the rear sub-frame 15 is provided with screw holes 15h. The number of holes 13h and holes 15h corresponds to the number of screws 9h. The screws 9h are inserted into the holes 13h and are screwed into the holes 15h.

The housing 35 is provided with an entrance 37 extending between the front side wall 3b of the front frame 3 and the rear side wall 5b of the rear frame 5. The entrance, which is in this example a slot, is situated opposite to the attaching device, particularly the screws 9h, and is closed by a cover 39. The cover is preferably a rim having dimensions corresponding to the dimensions of the slot-like entrance. In this example the rim-shaped cover 39 is provided with resilient hook-like edges 39a for fixing to the housing 35. In this way it is easy to remove the cover 39 from the housing 35 in order to reach the screws 9h, e.g. for service purposes of the display panel assembly 7. The cover 39 is made in this example of a non-transparent plastics. When service is desired, the cover 39 is simply removed for loosening the screws 9h. In this way the display panel assembly 7 can be opened without destroying the adhesion tape 9a during the product's lifecycle.

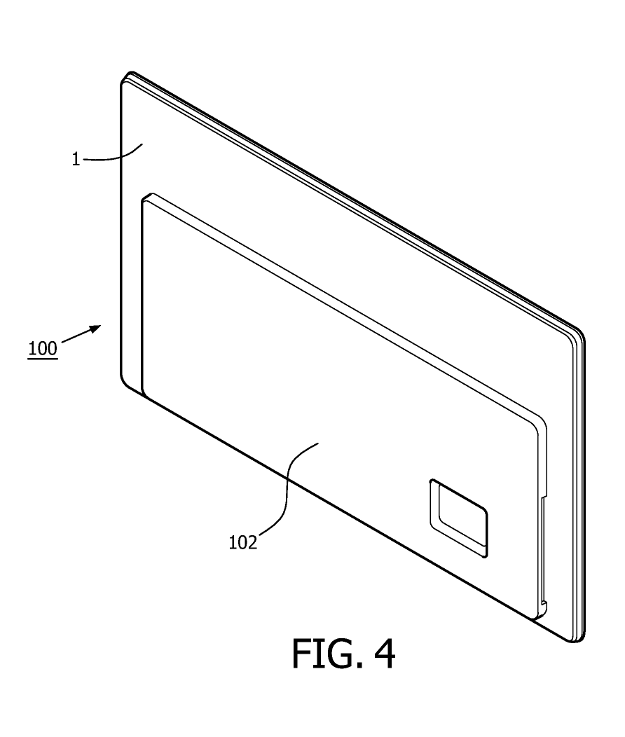

The display apparatus 100 depicted in FIG. 4 comprises a chassis 102, in this example a relatively small chassis, i.e. having dimensions in at least the width direction and height direction smaller than the corresponding dimensions of the display panel 1. The chassis 102 is mounted to the aesthetical rear frame 5 of the display panel device 1. The chassis 102 may be provided with components, not already provided into the display panel device 1. In the shown embodiment the display apparatus is a LED apparatus and is to be considered an example of a forward integration product. The display panel device 1 is the carrying part of the whole product.

While the invention has been illustrated and described in detail in the drawings and foregoing description, illustration and description are to be considered illustrative or exemplary and not restrictive. The invention is not limited to the disclosed embodiments. Other variations to the disclosed embodiments can be understood and effected by the skilled person in practicing the claimed invention, from a study of the drawings, the description and the claims. It is further noted that the system according to the invention and all its components can be made by applying processes and materials known per se. In the Claims and the description the word “comprising” does not exclude other elements, and the indefinite article “a” or “an” does not exclude a plurality. Any reference sign in the Claims should not be construed as limiting the scope.

1. A display panel device (1) comprising a front frame (3), a rear frame (5) and a display panel assembly (7) substantially positioned between the front frame and the rear frame, the front frame being provided with a front frame face (3a) directed to the display panel assembly and the rear frame being provided with a rear frame face (5a) directed to the display panel assembly, and further comprising a securing arrangement for mutually securing the front frame, the display panel assembly and the rear frame, wherein the securing arrangement includes a front sub-frame (13), a rear sub-frame (15) and an adhering provision (9a) for adhering the front sub-frame to the front frame face and for adhering the rear sub-frame to the rear frame face, and wherein the securing arrangement includes an attaching device (9b) for detachably attaching the front sub-frame and the rear sub-frame to each other.

2. The display panel device according to claim 1, wherein the display panel assembly is sandwiched between the front sub-frame (3) and the rear sub-frame (5).

3. The display panel device according to claim 1, wherein the front sub-frame (13) and the rear sub-frame (15) create an overlapping area (A), in which area the front sub-frame and the rear sub-frame are detachably attached to each other.

4. The display panel device according to claim 3, wherein the overlapping area (A) is formed by a front sub-frame part (13a) of the front sub-frame (13) and a rear sub-frame part (15a) of the rear sub-frame (15), wherein both sub-frame parts are substantially oriented perpendicularly to the front frame face (3a) and/or the rear frame face (3b).

5. The display panel device according to claim 1, wherein the attaching device (9b) includes a number of screws inserted into corresponding holes (13h;15h) provided into the sub-frames (13;15).

6. The display panel device according to claim 1, wherein the adhering provision includes an adhesive tape (9a).

7. The display panel device according to claim 6, wherein the adhesion tape (9a) is a double-sided adhesive tape.

8. The display panel device according to claim 6, wherein the adhesive tape (9a) loses its adhesive function above a predetermined temperature.

9. The display panel device according to claim 1, wherein the front frame (3) and the rear frame (5) constitute a housing (35) in which the securing arrangement (9a,9b) is accommodated.

10. The display panel device according to claim 9, wherein the housing (35) is provided with an entrance (37) substantially opposite to the attaching device (9b).

11. The display panel device according to claim 10, wherein the entrance (37) is closable by a removable cover (39).

12. The display panel device according to claim 10, wherein the entrance is formed by a circumferential gap (37) extending between a side wall (3b) of the front frame (3) and a side wall (5b) of the rear frame (5).

13. The display panel device according to claim 1, wherein the front frame (3) has the shape of a window frame and is provided with a display window (41).

14. The display panel device according to claim 1, wherein the rear frame (5) is plate-shaped.

15. A display apparatus (100) comprising the display panel device (1) according to claim 1.
